(19) United States
(12) Patent Application Publication
(10) Pub. No.: US 2003/0126543 A1
(43) Pub. Date: Jul. 3, 2003

(54) Method and apparatus for solving key equation polynomials in decoding error correction codes

(76) Inventors: Chen-Yi Lee, Hsinchu (TW); Hsie-Chia Chang, Hsinchu (TW)

Correspondence Address: PERKINS COIE LLP, P.O. BOX 2168, MENLO PARK, CA, 94026, US

(21) Appl. No.: 10/155,488

(22) Filed: May 22, 2002

(30) Foreign Application Priority Data
Nov. 28, 2001 (TW) 090129778

(51) Int. Cl. H03M 13/00

(52) U.S. Cl. 714/784

(57) ABSTRACT

The presently invention discloses a method for computing error locator polynomial and error evaluator polynomial in the key equation solving step of the error correction code decoding process whereby the polynomials are generated through at most t intermediate iterations that can be implemented with minimal amount of hardware circuitry. However, depending on the selected (N,K) code, the number of cycles required for the calculation of the polynomials would be within the time required for the calculation of upstream data. Additionally, the present invention for computing the error locator polynomial and the error value polynomial employs an efficient scheduling of a small number of registers and finite-field multipliers (FFMs) without the need of finite-field inverters (FFIs) is illustrated. Using these new methods, a new area-efficient architecture that uses only 4t+2ρ+4 registers and three FFMs and no FFIs is presented to implement the inversionless Euclidean algorithm.

### BACKGROUND OF THE INVENTION

In the transmission of data from a source location to a destination location through a variety of media, noise caused by the transmission path and/or the media itself causes errors in the transmitted data. Thus, the data transmitted is not the same as the data received. In order to determine the errors in the received data, various methods and techniques have been developed to detect and correct the errors in the received data. One of the methods is to generate a codeword which includes a message part (data to be transmitted) and a parity part (information for performing error correction).

Among the most well-known error-correcting codes, the BCH (Bose-Chaudhuri-Hocquenghen) codes and the RS (Reed-Solomon) codes are the most widely used block codes in the communication field and storage systems. The mathematical basis of BCH and RS codes is explained by: E. R. Berlekamp, Algebraic Coding Theory, McGraw-Hill, New York, 1968; and Richard E. Blahut, Theory and Practice of Error Control Codes, Addison-Wesley, 1983.

An (N, K) BCH or RS code has K message symbols and N coded symbols, where each symbol belongs to GF(q) for a BCH code or GF(q^{m}) for a RS code. A binary (N, K) BCH code can correct up to t errors with N=2m−1, N-K<=mt. An (N, K) RS code can correct up to t errors and ρ erasures with

$$t = ⌊ \frac{N - K - ρ}{2} ⌋ .$$

For binary BCH codes, an error can be corrected simply by finding out the error location. For RS codes, an error can be corrected by finding out the error location and the error value. In RS codes, an erasure is defined to be an error with a known error location, and hence its correction reduces to finding the error value.

The method steps for common popular RS decoder architectures for the correction of errors can be summarized into four steps: (1) calculating the syndromes from the received codewords, (2) computing the error locator polynomial and the error evaluator polynomial, (3) finding the error locations, and (4) computing error values. If both errors and erasures and corrected, the four steps are modified to: (1) calculating the Forney syndromes from the received codewords and the erasure locations, (2) computing the errata locator polynomial and the errata evaluator polynomial, (3) finding the errata locations, and (4) computing the errata values.

Referring to FIG. 1, the general decoding steps are illustrated. Note that for simplification, the error-only RS decoder is introduced. The received data, R(x), is provided to a syndrome generator 10,20 to generate a syndrome polynomial, S(x), representing the error pattern of the codeword from which the errors can be corrected. The syndrome is then provided to a key equation solver 12,22 to generate an error locator polynomial, σ(x), and an error evaluator polynomial, Ω(x). The error locator polynomial indicates the location(s) of the error and the error evaluator polynomial indicates the amount of the error. In the next step, the error locator polynomial is passed to a Chien search engine 14,24 to generate the root(s), β₁, representing the location(s) of the errors. Then the error evaluator 16,26 receiving the root(s) and the error evaluator polynomial, Ω(x), calculates the error value(s) of the root(s)

The second step in the above-mentioned four-step procedure involves solving the key equation, which is

S(x)σ(x)=Ω(x)mod x^{N-K} (1)

where S(x) is the syndrome polynomial, σ(x) is the error locator polynomial and Ω(x) is the error evaluator polynomial. When both errors and erasures are corrected, σ(x) and Ω(x) are the errata locator polynomial and the errata evaluator polynomial, respectively. In addition, the errata locator polynomial σ(x) becomes the product of λ(x) and Λ(x) corresponding to the error locator polynomial and the erasure locator polynomial, respectively.

The techniques frequently used to solve the key equation (1) include the Berlekamp-Massey algorithm and the Euclidean algorithm. The extension of these algorithms to correct both errors and erasures can be found in the Blahut article cited above. Here a novel invertionless decomposed Euclidean architecture is invented to reduce the hardware complexity drastically while maintaining the over all decoding speed.

Prior art technologies applied the traditional Euclidean algorithm (or variation thereof) for the calculation of the error locator polynomial and the error evaluator polynomial, and designed circuits based upon these algorithms. However, each of these algorithms require a large number of registers, finite-field multipliers (FFM) and perhaps a finite-field inverters (FFI). Each of the FFMs and FFI translates into a hardware circuitry and real estate on an integrated circuit chip. Therefore, the goal here is to derive a method for solving of the polynomials in an efficient manner and to minimize the amount of circuitry required in the implementation of the algorithm. The number of registers and FFMs is typically a function of the variable t. Table 1 illustrates the authors of the architectures for correcting error-only codewords and the corresponding number of registers, FFMs and FFI:

TABLE 1

| | Registers as a | FFMs as a | |
|---|---|---|---|
| Reference | function of t | function of t | FFI |
| Reed | 8t + 2 | 8t | 0 |
| Song | 6t + 4 | 6t + 2 | 0 |
| Wu | 7t + 5 | $t + ⌈ \frac{t + 1}{2} ⌉$ | 1 |

From Table 1, Reed proposed the implementation of the inversionless Euclidean algorithm requires 8t+2 registers, 8t FFMs and no FFI in VISI Implementation of A Pipeline Reed-Solomon Decoder, IEEE Transaction on Computers, vol. C-34, pp. 393-403, May 1985. In addition, the article An Efficient Architecture for Implementing the Modified Euclidean Algorithm, the 9^{th} NASA Symposium on VLSI Design, November 2000, Song demonstrated an architecture requiring 6t+4 registers and 6t+2 FFM's and no FFI.

On the other hand, the article An Area-efficient Versatile Reed-Solomon Decoder for ADSL, IEEE International Symposium on Circuits and Systems, May 1999, Wu et al. presented the architecture reducing the number of FFMs but requiring the relatively complex FFI, which will limit speed and impose a significant hardware complexity.

Therefore, it would be desirable to have an inversionless method and apparatus that requires no FFIs and minimizes the number of registers and FFMs in the implementation thereof.

### SUMMARY OF THE INVENTION

Accordingly, it is an object of the present invention to provide a method and apparatus for solving key equation polynomials in the decoding of codewords. Based upon the Euclidean algorithm, it can be implemented with minimal hardware circuitry.

It is another object of the present invention to provide a method and apparatus for solving key equation within a t-step iterative decoding procedure while the prior art architectures require at most 2t iterations.

It is yet another object of the present invention to provide a method and apparatus for solving key equation polynomials without decreasing the overall decoding speed of the decoder.

Briefly, in a presently preferred embodiment, a method for computing error locator polynomial and error evaluator polynomial in the key equation solving step of the error correction code decoding process is presented whereby the polynomials are generated through at most t intermediate iterations that can be implemented with minimal amount of hardware circuitry. However, depending on the selected (N,K) code, the number of cycles required for the calculation of the polynomials would be within the time required for the calculation of upstream data.

Additionally, a presently preferred embodiment for computing the error locator polynomial and the error value polynomial employs an efficient scheduling of a small number of registers and finite-field multipliers (FFMs) without the need of finite-field inverters (FFIs) is illustrated. Using these new methods, a new area-efficient architecture that uses only 4t+2ρ+2 registers and three FFMs and no FFIs is presented to implement the inversionless Euclidean algorithm. This method and architecture can be applied to a wide variety of RS and BCH codes with suitable code sizes.

More specifically, the 3-FFM architecture of the presently preferred embodiment for solving key equation polynomials can also be utilized to calculate the Forney syndrome polynomial T(x) described above. This method and architecture can be applied to correct the error-only as well as the error-and-erasure codewords.

An advantage of the present invention is that it provides a method and apparatus for solving key equation polynomials in the decoding of codewords. Based upon the Euclidean algorithm, it can be implemented with minimal hardware circuitry.

Another advantage of the present invention is that it provides a method and apparatus for solving key equation polynomials within a t-iteration decoding procedure while other architectures require at most 2t iterations. It will maintain the overall decoding speed of the decoder.

Yet another advantage of the present invention is that it provides an identical method and apparatus for not only solving key equation polynomials but also calculating the Forney syndrome polynomial T(x). It can be applied to the correction of errors as well as erasures.

### BRIEF DESCRIPTION OF THE DRAWINGS

FIGS. 1a and 1b illustrates the processing blocks in the decoding or codewords;

FIG. 2a˜FIG. 2c shows a three-FFM architecture of the preferred embodiment for calculating the errata evaluator polynomial, Ω(x), in the key equation solver.

FIG. 2d shows a three-FFM architecture of the preferred embodiment for calculating the errata location polynomial, σ(x), in the key equation solver.

FIG. 2e shows a three-FFM architecture of the preferred embodiment for calculating the Forney syndrome, T(x).

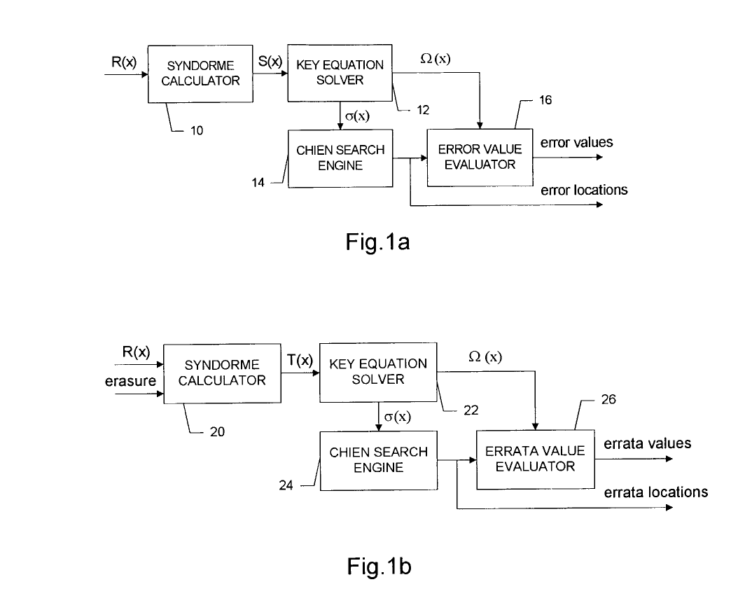

### DESCRIPTION OF THE PREFERRED EMBODIMENTS

Firstly, we will show our modified decoding procedure requiring at most t iterations while the previous decoding procedure requires at most 2t iteration. Following the inversionless Euclidean algorithm is illustrated and the errata value(s) and errata location(s) produced by \hat{Ω}(x) and \hat{σ}(x) in our inversionless decoding procedure are identical to the errata value(s) and errata location(s) founded by Ω(x) and σ(x) in the original algorithm. Secondly, we decompose the inversionless Euclidean algorithm for reducing the number of registers to 4t+2ρ+2 and the number of FFMs to 3. Finally, we show the condition on N, K such that our architecture can be applied.

The Euclidean Decoding Procedure

For illustrating the Euclidean algorithm, we rewrite (1) as:

Ω(x)=x^{N-K}Q(x)+T(x)λ(x) (2)

where Q(x) is the quotient polynomial of x^{N-K} and T(x)λ(x), T(x)=S(x)Λ(x) is the Forney syndrome polynomial, and σ(x)=λ(x)Λ(x) is the errata locator polynomial, which is the product of the error locator polynomial, λ(x), and the erasure locator polynomial, Λ(x). Therefore, the errata evaluator polynomial, Ω(x), can be calculated by the similar process of computing the GCD polynomial of x^{N-K} and T(x) through the Euclidean algorithm, whose decoding process can be shown as follows:

R⁽⁻¹⁾(x)=x^{N-K}

R⁽⁰⁾(x)=T(x)

R⁽¹⁾(x)=R⁽⁻¹⁾(x)−R⁽⁰⁾(x)·Q⁽¹⁾(x)

R⁽ⁱ⁾(x)=R⁽ⁱ⁻²⁾(x)−R⁽ⁱ⁻¹⁾(x)·Q⁽ⁱ⁾(x) (3)

where Q⁽ⁱ⁾(x) is the i-th quotient polynomial and R⁽ⁱ⁾(x) is the i-th remainder polynomial. Each iterative step in (4) performs a polynomial division operation. Note that the i-th dividend polynomial R⁽ⁱ⁻²⁾(x) and the i-th divisor polynomial R⁽ⁱ⁻¹⁾(x) are equivalent to the (i−2)-th and the (i−1)-th remainder polynomials respectively. After n division operations, the n-th remainder polynomial, R⁽ⁿ⁾(x), is assumed to be the errata evaluator polynomial Ω(x). From the extended form of Euclidean algorithm introduced by Error-Control Coding for Data Networks, Kluwer Academic, 1999, the similar decoding process except the minor difference in the initial condition can be used to determine the errata locator polynomial σ(x), which is also described as follows:

μ⁽⁻¹⁾(x)=0

μ⁽⁰⁾(x)=Λ(x)

μ⁽¹⁾(x)=μ⁽⁻¹⁾(x)+μ⁽⁰⁾(x)·Q⁽²⁾(x)

μ⁽ⁱ⁾(x)=μ⁽ⁱ⁻²⁾(x)+μ⁽ⁱ⁻¹⁾(x)·Q⁽ⁱ⁾(x) (4)

where

$$Λ ( x ) = {Π}_{{α}^{i} ∈ Λ} ( 1 + {α}^{i} x )$$

represents the erasure locator polynomial and Λ is the erasure set. Note that all Q⁽ⁱ⁾(x) here are equivalent to the i-th quotient polynomial Q⁽ⁱ⁾(x) in (3). Similarly, after n iterations, μ⁽ⁿ⁾(x) is assumed to the errata locator polynomial, σ(x). From (3) and (4), it can be shown that the sum of deg(R⁽ⁱ⁻¹⁾(x)) and deg(μ⁽ⁱ⁾(x)) equals to a constant number, N-K+s, where s is the number of actual erasures and hence, equals the degree of Λ(x).

Our Modified Decoding Procedure

The proposed modified decoding procedure calculating the quotient polynomial with degree one in advance is shown as follows:

Initial Condition

A⁽⁰⁾(x)=x^{N-K}, M⁽⁰⁾(x)=Ω⁽⁰⁾(x)=T(x)

a⁽⁰⁾(x)=0, m⁽⁰⁾(x)=σ⁽⁰⁾(x)=Λ(x)

For(i=0 to t)

δ=deg(A⁽ⁱ⁾(x)), Δ=deg(M⁽ⁱ⁾(x))

if(deg(σ⁽ⁱ⁾(x))≦deg(Ω⁽ⁱ⁾(x))

$$\begin{matrix}{q}_{1}^{( i )} ( x ) = \frac{{A}_{δ}^{( i )}}{{M}_{Δ}^{( i )}} & \\ {q}_{0}^{( i )} ( x ) = 0 & for δ = Δ \\ {q}_{0}^{( i )} ( x ) = \frac{{M}_{Δ}^{( i )} {A}_{δ - 1}^{( i )} + {M}_{Δ - 1}^{( i )} {A}_{δ}^{( i )}}{{M}_{Δ}^{( i )} {M}_{Δ}^{( i )}} & for δ \neq Δ\end{matrix}$$

Ω⁽ⁱ⁺¹⁾(x)=A⁽ⁱ⁾(x)+x^{δ-Δ-1}·M⁽ⁱ⁾(x)·q⁽ⁱ⁾(x) (5)

σ⁽ⁱ⁺¹⁾(x)=a⁽ⁱ⁾(x)+x^{δ-Δ-1}·m⁽ⁱ⁾(x)·q⁽ⁱ⁾(x) (6)

if(deg(Ω⁽ⁱ⁺¹⁾(x))<Δ)

A⁽ⁱ⁺¹⁾(x)=M⁽ⁱ⁾(x), M⁽ⁱ⁺¹⁾(x)=Ω⁽ⁱ⁺¹⁾(x)

a⁽ⁱ⁺¹⁾(x)=m⁽ⁱ⁾(x), m⁽ⁱ⁺¹⁾(x)=σ⁽ⁱ⁺¹⁾(x)

else

A⁽ⁱ⁺¹⁾(x)=Ω⁽ⁱ⁺¹⁾(x), M⁽ⁱ⁺¹⁾(x)=M⁽ⁱ⁾(x)

a⁽ⁱ⁺¹⁾(x)=σ⁽ⁱ⁺¹⁾(x), m⁽ⁱ⁺¹⁾(x)=m⁽ⁱ⁾(x)

else

Ω(x)=Ω⁽ⁱ⁾(x), σ(x)=σ⁽ⁱ⁾(x) Finish

where q⁽ⁱ⁾(x)=q₁⁽ⁱ⁾x+q₀⁽ⁱ⁾ is the i-th dummy quotient polynomial, Ω⁽ⁱ⁺¹⁾(x) is the i-th dummy remainder polynomial, and A_{δ}⁽ⁱ⁾ and M_{Δ}⁽ⁱ⁾ are the leading coefficients of the i-th dummy dividend polynomial A⁽ⁱ⁾(x) with degree of δ and the i-th dummy remainder polynomial with degree of Δ, respectively. Note that if there are only errors, the erasure locator polynomial, Λ(x) equals 1 and the Forney syndrome polynomial, T(x) should be altered to the syndrome polynomial S(x).

As compared with (3), if we assume the i-th dividend polynomial R⁽ⁱ⁻²⁾(x) to A⁽ⁱ⁾(x) as well as the i-th divisor polynomial R⁽ⁱ⁻¹⁾(x) to M⁽ⁱ⁾(x), the difference in degree between A⁽ⁱ⁾(x) and M⁽ⁱ⁾(x) equaling δ−Δ implies the decoding procedure shown above will take at most

$$⌈ \frac{δ - Δ + 1}{2} ⌉$$

iterations to calculate the i-th remainder polynomial R⁽ⁱ⁾(x).

Note that our modified decoding procedure will stop at deg(Ω⁽ⁱ⁾(x))<deg(σ⁽ⁱ⁾(x)) and in the meantime, σ⁽ⁱ⁾(x) is the errata locator polynomial σ(x) with degree of s+ν. That s and ν represent the number of actual erasure(s) and error(s). Recalling deg(σ⁽⁰⁾(x))=deg(Λ(x))=s, the degree of σ⁽ⁱ⁾(x) will increase from s to s+ν. In a specific case with degree of Q⁽ⁱ⁾(x) in (3) all equaling one, ν division operations are needed and in the decoding procedure shown above, the total number of iterations is ν as a result that accomplishing each division operation takes 1 iteration with δ−Δ=deg(q⁽ⁱ⁾(x))=1. Owing to ν≦t, the modified decoding procedure above requires at most t iterations for solving key equation polynomials.

The Inversionless Decoding Procedure

For eliminating the inverse operation within our modified decoding procedure, a novel inversionless decoding procedure is proposed and shown as follows:

Initial Condition:

Â⁽⁰⁾(x)=x^{N-K}, \hat{M}⁽⁰⁾(x)=\hat{Ω}⁽⁰⁾(x)=T(x)

â⁽⁰⁾(x)=0, \hat{m}⁽⁰⁾(x)=\hat{σ}⁽⁰⁾(x)=Λ(x)

For (i=0 to t)

δ=deg(Â⁽ⁱ⁾(x)), Δ=deg(\hat{M}⁽ⁱ⁾(x))

if(deg(\hat{σ}⁽ⁱ⁾(x))≦deg(\hat{Ω}⁽ⁱ⁾(x)))

\hat{q}₁⁽ⁱ⁾(x)=Â_{δ}⁽ⁱ⁾\hat{M}_{Δ}⁽ⁱ⁾

\hat{q}₀⁽ⁱ⁾(x)=0 for δ≠Δ

\hat{q}₀⁽ⁱ⁾(x)=\hat{M}_{Δ}⁽ⁱ⁾Â_{δ-1}⁽ⁱ⁾+\hat{M}_{Δ-1}⁽ⁱ⁾Â_{δ}⁽ⁱ⁾ for δ=Δ

\hat{Ω}⁽ⁱ⁺¹⁾(x)=\hat{M}_{Δ}⁽ⁱ⁾\hat{M}_{Δ}⁽ⁱ⁾·Â⁽ⁱ⁾(x)+x^{δ-Δ-1}·\hat{M}⁽ⁱ⁾(x)·\hat{q}⁽ⁱ⁾(x) (7)

\hat{σ}⁽ⁱ⁺¹⁾(x)=\hat{M}_{Δ}⁽ⁱ⁾\hat{M}_{Δ}⁽ⁱ⁾·â⁽ⁱ⁾(x)+x^{δ-Δ-1}·\hat{m}⁽ⁱ⁾(x)·\hat{q}⁽ⁱ⁾(x) (8)

if(deg(\hat{Ω}⁽ⁱ⁺¹⁾(x))<Δ)

Â⁽ⁱ⁺¹⁾(x)=\hat{M}⁽ⁱ⁾(x), \hat{M}⁽ⁱ⁺¹⁾(x)=\hat{Ω}⁽ⁱ⁺¹⁾(x)

â⁽ⁱ⁺¹⁾(x)=\hat{m}⁽ⁱ⁾(x), \hat{m}⁽ⁱ⁺¹⁾(x)=\hat{σ}⁽ⁱ⁺¹⁾(x)

else

Â⁽ⁱ⁺¹⁾(x)=\hat{Ω}⁽ⁱ⁺¹⁾(x), \hat{M}⁽ⁱ⁺¹⁾(x)=\hat{M}⁽ⁱ⁾(x)

â⁽ⁱ⁺¹⁾(x)=\hat{σ}⁽ⁱ⁺¹⁾(x), \hat{m}⁽ⁱ⁺¹⁾(x)=\hat{m}⁽ⁱ⁾(x)

else

\hat{Ω}(x)=\hat{Ω}⁽ⁱ⁾(x), \hat{σ}(x)=\hat{σ}⁽ⁱ⁾(x) Finish

where \hat{Ω}(x) and \hat{σ}(x) are the modified errata evaluator polynomial and errata locator polynomial, respectively, It can be shown that \hat{σ}(x) and \hat{Ω}(x) can be used to find the same error location(s) and error value(s) as the original σ(x) and Ω(x) do. While compared with other approaches, our proposed inversionless Euclidean algorithm not only eliminates the costly inversion operation but also introduces a t-iteration decoding procedure.

The Decomposed Architecture

Here we propose a decomposed architecture from the proposed inversionless Euclidean algorithm, which works with individual coefficients of the polynomial instead of the entire polynomial as a whole.

And (7)˜(8) can be decomposed as the following two equations:

\hat{Ω}ⱼ⁽ⁱ⁺¹⁾=\hat{M}_{Δ}⁽ⁱ⁾\hat{M}_{Δ}⁽ⁱ⁾·Âⱼ⁽ⁱ⁾+\hat{M}_{j-(δ-Δ-1)}⁽ⁱ⁾·\hat{q}₀⁽ⁱ⁾+\hat{M}_{j-(δ-Δ)}⁽ⁱ⁾·\hat{q}₁⁽ⁱ⁾ 0≦j≦δ−2 (9)

\hat{σ}ₖ⁽ⁱ⁺¹⁾=\hat{M}_{Δ}⁽ⁱ⁾\hat{M}_{Δ}⁽ⁱ⁾·âₖ⁽ⁱ⁾+\hat{m}_{k-(δ-Δ-1)}⁽ⁱ⁾·\hat{q}₀⁽ⁱ⁾+\hat{m}_{k-(δ-Δ)}⁽ⁱ⁾·\hat{q}₁⁽ⁱ⁾ 0≦k≦φ (10)

where δ and Δ represent the degree of Â⁽ⁱ⁾(x) and \hat{M}⁽ⁱ⁾(x) respectively, and \hat{Ω}ⱼ⁽ⁱ⁺¹⁾ and \hat{σ}ₖ⁽ⁱ⁺¹⁾ corresponds to the j-th and k-th coefficient of \hat{Ω}⁽ⁱ⁺¹⁾(x) with degree of δ−2 and \hat{σ}⁽ⁱ⁺¹⁾(x) with degree of φ at the i-th iteration. From (9)˜(10), if \hat{M}_{Δ}⁽ⁱ⁾\hat{M}_{Δ}⁽ⁱ⁾, \hat{q}₀⁽ⁱ⁾ and \hat{q}₁⁽ⁱ⁾ can be calculated in advance, there only three finite-field multiplications needed to compute \hat{Ω}ⱼ⁽ⁱ⁺¹⁾ and \hat{σ}ₖ⁽ⁱ⁺¹⁾. The detailed cycle operation of our inversionless decomposed architecture can be seen in Table 2. For simplifying notations, we let δ−Δ=1 without loss of generality.

TABLE 2

| | |
|---|---|
| Cycle | \hat{Ω}⁽ⁱ⁺¹⁾ (x) and \hat{σ}⁽ⁱ⁺¹⁾ (x) |

| | | | |
|---|---|---|---|
| Initial- | w = \hat{M}_{Δ}⁽ⁱ⁾\hat{M}_{Δ}⁽ⁱ⁾ | | |
| ization | \hat{q}₀⁽ⁱ⁾ = \hat{M}_{Δ}⁽ⁱ⁾Â_{δ-1}⁽ⁱ⁻¹⁾ + | \hat{M}_{Δ-1}⁽ⁱ⁾Â_{δ}⁽ⁱ⁻¹⁾ | |
| j = 0 | \hat{q}₁⁽ⁱ⁾ = \hat{M}_{Δ}⁽ⁱ⁾Â_{δ}⁽ⁱ⁻¹⁾ | | |
| | \hat{Ω}₀⁽ⁱ⁺¹⁾ = w · Â₀⁽ⁱ⁻¹⁾ + | \hat{M}₀⁽ⁱ⁾ · \hat{q}₀⁽ⁱ⁾ | |
| j = 1 | \hat{Ω}₁⁽ⁱ⁺¹⁾ = w · Â₁⁽ⁱ⁻¹⁾ + | \hat{M}₁⁽ⁱ⁾ · \hat{q}₀⁽ⁱ⁾ + | \hat{M}₀⁽ⁱ⁾ · \hat{q}₁⁽ⁱ⁾ |
| | . . . | | |
| j = δ − | \hat{Ω}_{δ-2}⁽ⁱ⁺¹⁾ = w · Â_{δ-2}⁽ⁱ⁻¹⁾ + | \hat{M}_{Δ-1}⁽ⁱ⁾ · \hat{q}₀⁽ⁱ⁾ + | \hat{M}_{Δ-2}⁽ⁱ⁾ · \hat{q}₁⁽ⁱ⁾ |
| 2 | | | |
| j = δ − | \hat{Ω}_{δ-1}⁽ⁱ⁺¹⁾ = w · Â_{δ-1}⁽ⁱ⁻¹⁾ + | \hat{M}_{Δ}⁽ⁱ⁾ · \hat{q}₀⁽ⁱ⁾ + | \hat{M}_{Δ-1}⁽ⁱ⁾ · \hat{q}₁⁽ⁱ⁾ = 0 |
| 1 | | | |
| j = δ | \hat{Ω}_{δ}⁽ⁱ⁺¹⁾ = w · Â_{δ}⁽ⁱ⁻¹⁾ | + | \hat{M}_{Δ}⁽ⁱ⁾ · \hat{q}₁⁽ⁱ⁾ = 0 |
| k = 0 | \hat{σ}₀⁽ⁱ⁺¹⁾ = w · â₀⁽ⁱ⁾ + | \hat{m}₀⁽ⁱ⁾ · \hat{q}₀⁽ⁱ⁾ | |
| k = 1 | \hat{σ}₁⁽ⁱ⁺¹⁾ = w · â₁⁽ⁱ⁾ + | \hat{m}₁⁽ⁱ⁾ · \hat{q}₀⁽ⁱ⁾ + | \hat{m}₀⁽ⁱ⁾ · \hat{q}₁⁽ⁱ⁾ |
| | . . . | | |
| k = ψ − | \hat{σ}_{ψ-1}⁽ⁱ⁺¹⁾ = w · â_{ψ-1}⁽ⁱ⁾ | \hat{m}_{ψ-1}⁽ⁱ⁾ · \hat{q}₀⁽ⁱ⁾ + | \hat{m}_{ψ-2}⁽ⁱ⁾ · \hat{q}₁⁽ⁱ⁾ |
| 1 | | | |
| k = ψ | \hat{σ}_{ψ}⁽ⁱ⁺¹⁾ = w · â_{ψ}⁽ⁱ⁾ | \hat{m}_{ψ}⁽ⁱ⁾ · \hat{q}₀⁽ⁱ⁾ | \hat{m}_{ψ-1}⁽ⁱ⁾ · \hat{q}₁⁽ⁱ⁾ |

It is evident from Table 1 that, at cycle j=0, the computation of \hat{Ω}₀⁽ⁱ⁺¹⁾ requires w=\hat{M}_{Δ}⁽ⁱ⁾\hat{M}_{Δ}⁽ⁱ⁾ and \hat{q}₀⁽ⁱ⁾, which have been calculated at the initialization cycle. Similarly, at cycle j≧1, the computation of \hat{Ω}ⱼ⁽ⁱ⁺¹⁾ also requires \hat{q}₁⁽ⁱ⁾, which has been calculated at cycle j=0. Note that each cycle needs three finite-field multiplications and the calculations process of \hat{σ}⁽ⁱ⁺¹⁾(x) is similar to that of \hat{Ω}⁽ⁱ⁺¹⁾(x).

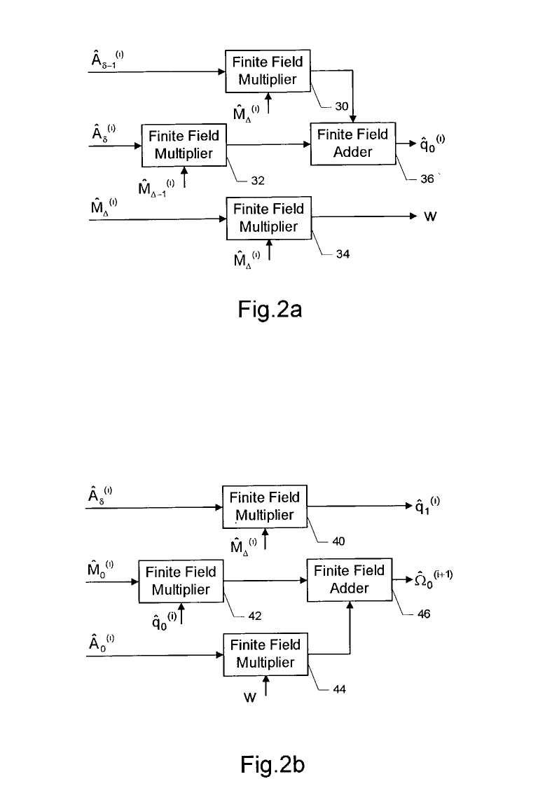

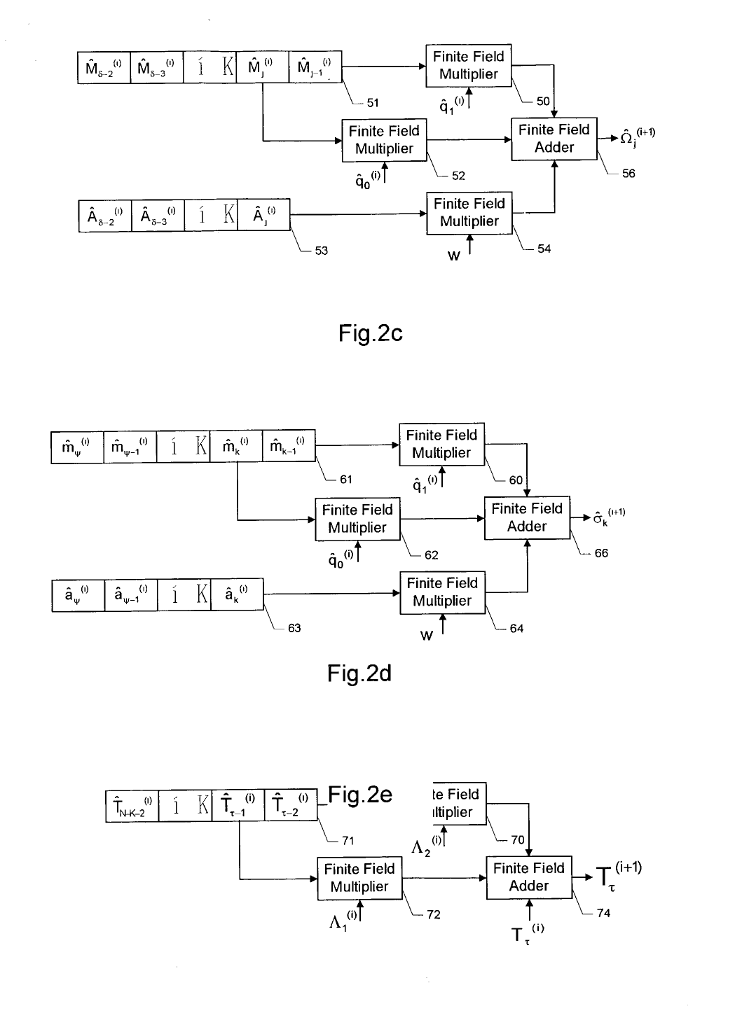

The inversionless decomposed Euclidean algorithm shown above suggests a 3-FFM implementation of the key equation solver, which is illustrated in FIG. 2. The branch labeling in FIG. 2 corresponds to a particular time instance. As compared with Table 1, FIG. 2(a) shows the initialization cycle, when j=0, refer to Table 1, is w=\hat{M}_{Δ}⁽ⁱ⁾\hat{M}_{Δ}⁽ⁱ⁾ is computed by a finite field multiplier 34, equation \hat{q}₀⁽ⁱ⁾(x)=\hat{M}_{Δ}⁽ⁱ⁾Â_{δ-1}⁽ⁱ⁻¹⁾+\hat{M}_{Δ-1}⁽ⁱ⁾Â_{δ}⁽ⁱ⁻¹⁾, wherein \hat{M}_{Δ}⁽ⁱ⁾Â_{δ-1}⁽ⁱ⁻¹⁾ is computed by a finite field multiplier 30, \hat{M}_{Δ-1}⁽ⁱ⁾Â_{δ}⁽ⁱ⁻¹⁾ is computed by a finite field multiplier 32, these two terms are added by a finite field adder 36 to have \hat{q}₀⁽ⁱ⁾, as shown in FIG. 2a. FIG. 2(b) indicates the calculation cycle for \hat{q}₁⁽ⁱ⁾ and \hat{Ω}₀⁽ⁱ⁺¹⁾. Since \hat{q}₁⁽ⁱ⁾=\hat{M}_{Δ}⁽ⁱ⁾Â_{δ}⁽ⁱ⁻¹⁾, the finite field multiplier 40 is used to compute \hat{q}₁⁽ⁱ⁾, since \hat{Ω}₀⁽ⁱ⁺¹⁾=w·Â₀⁽ⁱ⁻¹⁾+\hat{M}₀⁽ⁱ⁾·\hat{q}₀⁽ⁱ⁾, the finite field multiplier 44 realize w·Â₀⁽ⁱ⁻¹⁾ and the finite field multiplier 42 realize \hat{M}₀⁽ⁱ⁾·\hat{q}₀⁽ⁱ⁾, these two terms are added by a finite field adder 36 to have \hat{Ω}₀⁽ⁱ⁺¹⁾.

The process for computing other coefficients of \hat{Ω}⁽ⁱ⁺¹⁾(x) is expressed in FIG. 2(c), when j≧1, refer to Table 1, \hat{Ω}⁽ⁱ⁺¹⁾(x) can be obtained by finite field multiplier 50,52,54 and a finite field adder 56. Because the computation process of \hat{σ}⁽ⁱ⁺¹⁾(x) is similar to that of \hat{Ω}⁽ⁱ⁺¹⁾(x), the hardware used to compute \hat{Ω}⁽ⁱ⁺¹⁾(x) can be reconfigured to calculated \hat{σ}⁽ⁱ⁺¹⁾(x), which is presented in FIG. 2(d), the hardware is similar to FIG. 2c, with multipliers 60,62,64 and an adder 66 to compute \hat{σ}⁽ⁱ⁺¹⁾(x) for k=1 to ψ, as illustrate in Table 1.

This architecture can be used for error-only correction as well as error-and-erasure correction. Compared to existing proposals requiring 6t to 8t FFMs, the preferred embodiment of the present invention significantly reduces hardware complexity down to 3 FFMs. However, in order to finish the i-th iteration, the architecture of the preferred embodiment requires δ+ψ+1 cycles whereas prior art architectures requires only two to three cycles. The additional time required for generating the data under the architecture of the present invention does not slow down the overall system processing speed. Due to the overall system processing speed dominated by the syndrome calculator and Chien Search, each taking N cycles to finish, our architecture slowing down the Euclidean algorithm (till taking N cycles) will not impact the decoding speed.

Additionally, the method and apparatus of the present invention also minimize the amount of required registers. Recalling (9) and (10), ψ representing the degree of \hat{σ}⁽ⁱ⁺¹⁾(x) is equivalent to the degree of μ⁽ⁱ⁾(x) in (4) and similarly, Δ representing the degree of \hat{M}⁽ⁱ⁾(x) is equivalent to that of R⁽ⁱ⁻¹⁾(x) in (3). As shown earlier, deg(μ⁽ⁱ⁾(x))+deg(R⁽ⁱ⁻¹⁾(x))=N-K+s≦2t+ρ, where t and ρ represent the number of errors and erasures in the decoding of codewords and consequently, in the preferred embodiment of the present invention, 2t+ρ+2 registers are used to store the coefficients of \hat{M}⁽ⁱ⁾(x) and \hat{σ}⁽ⁱ⁺¹⁾(x), and another 2t+ρ registers can be used for storing the coefficients of \hat{m}⁽ⁱ⁾(x) and \hat{Ω}⁽ⁱ⁺¹⁾(x). Hence, calculating \hat{Ω}⁽ⁱ⁺¹⁾(x) and \hat{σ}⁽ⁱ⁺¹⁾(x) iteratively totally requires 4t+2ρ+2 registers and if there are only errors corrected, the amount of required registers is 4t+2 and the previously proposed architectures requiring 6t to 8t registers.

Furthermore, the preferred embodiment of the present invention can also be used to calculate the Forney syndrome polynomial, T(x), which is defined as:

T(x)=S(x)Λ(x)mod x^{N-K} (11)

where

$$Λ ( x ) = {\prod }_{j = 1}^{s} ( 1 + {χ}_{j} x )$$

is the erasure locator polynomial and χⱼ is the j-th erasure magnitude. T(x) can be obtained by following procedures:

Initial Condition

T⁽⁰⁾(x)=S(x)

For(i=0 to t)

if(2i<s)

Λ⁽ⁱ⁾(x)=(1+χ₂ᵢx)(1+χ₂ᵢ₊₁x) (12)

T⁽ⁱ⁺¹⁾(x)=T⁽ⁱ⁾(x)·Λ⁽ⁱ⁾(x)mod X^{N-K} (13)

else

T(x)=T⁽ⁱ⁾(x) Finish

where Λ⁽ⁱ⁾(x) is the i-th auxiliary polynomial for computing the i-th iteration Fonrey syndrome polynomial, T⁽ⁱ⁺¹⁾(x). Note that Λ⁽ⁱ⁾(x) can be expressed as 1+Λ₁⁽ⁱ⁾x+Λ₂⁽ⁱ⁾x² and T⁽ⁱ⁺¹⁾(x) can be decomposed as the following results:

T_{τ}⁽ⁱ⁺¹⁾=T_{τ}⁽ⁱ⁾+T_{τ-1}⁽ⁱ⁾·Λ₁⁽ⁱ⁾+T_{τ-2}⁽ⁱ⁾·Λ₂⁽ⁱ⁾ 0≦τ≦N-K−1 (14)

It is evident that the process calculating the τ-th coefficient, T_{τ}⁽ⁱ⁺¹⁾, is very similar to (9) or (10), and therefore, the 3-FFM architecture can be used to obtain the Forney syndrome polynomial T(x), which is illustrated in FIG. 2(e), as refer to equation (14), the second term is computed by a finite field multiplier72, the third term is computed by a finite field multiplier70 and these two terms and the first term are added by a finite field adder 74 to have T_{τ}⁽ⁱ⁺¹⁾.

Application Conditions

The total number of cycles required to compute \hat{σ}(x) and \hat{Ω}(x) using the 3-FFM architecture of the preferred embodiment is of interest in considering the potential impact on the overall system performance. From the proposed iterative decoding process, 0≦j≦δ−2 in (9) and 0≦λ≦ψ in (10) implying the number of cycles required to compute \hat{Ω}⁽ⁱ⁺¹⁾(x) is δ−1 and calculating \hat{σ}⁽ⁱ⁺¹⁾(x) needs ψ+1 cycles in the i-th iteration. However, one more cycles is needed to get \hat{q}₁⁽ⁱ⁾ and \hat{q}₀⁽ⁱ⁾, and the proposed decoding procedure requires δ+ψ+1 cycles in one iteration totally. From ψ+Δ=N-K+s and δ−Δ≦1, it is clear that δ+ψ+1≦N-K+s+2≦2t+ρ+2. For RS (N,K) code for correcting t errors and ρ erasures, the total number of cycles required in our t-iteration decomposed inversionless architecture is less than 2t²+ρt+2t. Table 3 shows the maximum number of cycles for different RS (N,K) codes with N-K ranging from 4 to 16. If N is larger than the number of cycles required, then our 3-FFMs architecture can be applied to reduce the hardware complexity while maintaining the overall decoding speed.

TABLE 3

| N − K | t | ρ | cycles | t | ρ | Cycles |
|---|---|---|---|---|---|---|
| 4 | 2 | — | 12 | 1 | 2 | 6 |
| 6 | 3 | — | 24 | 2 | 2 | 16 |
| 8 | 4 | — | 40 | 3 | 2 | 30 |
| 10 | 5 | — | 60 | 4 | 2 | 48 |
| 12 | 6 | — | 84 | 5 | 2 | 70 |
| 14 | 7 | — | 112 | 6 | 2 | 96 |
| 16 | 8 | — | 144 | 7 | 2 | 126 |

There are many applications of BCH and RS codes in communications and storage systems that benefit from methods and apparatus of the present invention. For example, Digital Versatile Disks (DVDs) use a RS product code which is (182,172) in the row direction and (208,192) in the column direction. Digital TV broadcasting uses a (204,188) RS code. CD-ROM uses a number of smaller (32,28) and (28,24) RS codes. In the optical fiber submarine cable systems, RS (255,239) code is used and standardized to provide burst error correcting capability. In wireless communications, the AMPS cellular phone system uses (40,28) and (48,36) binary BCH codes, which are shortened codes of the (63,51) code. The (63,51) code, which can correct up to 2 errors (N-K=12,m=6), requires fewer than 12 cycles (t=2, row 1 of Table 3). All of these applications, as well as many others, can benefit from the method and apparatus of the present invention.

Although the present invention has been described in terms of specific embodiments, it is anticipated that alterations and modifications thereof will no doubt become apparent to those skilled in the art. It is therefore intended that the following claims be interpreted as covering all such alterations and modifications as fall within the true spirit and scope of the invention.

What is claimed is:

1. An apparatus for solving key equation polynomials in decoding error correction codes, a novel inversionless decomposed architecture which is frequently used in BCH and Reed-Solomon decoders comprising:
a syndrome calculator that received codewords and output a syndrome polynomial to a key equation solver;
a key equation solver that calculated error locator polynomial and error evaluator polynomial and output error location;
a Chein Search that received said error locator polynomial and input a result to an error value calculator and output said error location;
an error value calculator that received signal from said key equation solver and Chein Search, output an error value.

2. An apparatus for solving key equation polynomials in decoding error correction codes according to claim 1, wherein said apparatus is used for BCH and Reed-Solomon (RS) decoders.

3. An apparatus for solving key equation polynomials in decoding error correction codes according to claim 1, wherein said apparatus is applied to BCH and Reed-Solomon (RS) decoders which is a kind of inversionless decomposed architecture.

4. An apparatus for solving key equation polynomials in decoding error correction codes according to claim 1, wherein said apparatus can be applied to the correction of errors as well as erasures.

5. An apparatus for solving key equation polynomials in decoding error correction codes in claim 1, wherein said method and apparatus is applied in inversionless Euclidean.

6. An apparatus for solving key equation polynomials in decoding error correction codes according to claim 1, wherein said apparatus can eliminate the finite-field inverter (FFI) to finish.

7. An apparatus for solving key equation polynomials in decoding error correction codes according to claim 1, wherein said apparatus is only needed t iteration decoding procedure.

8. An apparatus for solving key equation polynomials in decoding error correction codes according to claim 1, wherein said apparatus including said decomposed technique which can also drastically reduce the required number of finite-field multipliers (FFMs) from 4t˜6t to 3.

9. An apparatus for solving key equation polynomials in decoding error correction codes according to claim 1, wherein said apparatus including said decomposed technique that uses only 4t+2ρ+4 registers.

10. An apparatus for solving key equation polynomials in decoding error correction codes according to claim 1, wherein said apparatus including said decomposed technique that no FFIs is presented to implement the inversionless Euclidean algorithm.

11. An apparatus for solving key equation polynomials in decoding error correction codes according to claim 1, wherein said apparatus can use to calculate the Forney syndrome polynomial.

12. An apparatus for solving key equation polynomials in decoding error correction codes according to claim 1, wherein said apparatus is further operable in communication.

13. A method for solving key equation polynomials in decoding error correction codes. In particular, a novel method for inversionless decomposed architecture which is frequently used in BCH and Reed-Solomon decoders executable instructions for:
(a) received said codewords and calculate said syndrome;
(b) produced said errata locator polynomial and errata evaluator polynomial;
(c) search said error location;
(d) calculated said error value.

14. A method for solving key equation polynomials in decoding error correction codes according to claim 13, wherein said method is used for BCH and Reed-Solomon (RS) decoders.

15. A method for solving key equation polynomials in decoding error correction codes according to claim 13, wherein said method is applied to BCH and Reed-Solomon (RS) decoders which is a kind of inversionless decomposed architecture.

16. A method for solving key equation polynomials in decoding error correction codes according to claim 13, wherein said method can be applied to the correction of errors as well as erasures.

17. A method for solving key equation polynomials in decoding error correction codes according to claim 13, wherein said method is applied in inversionless Euclidean.

18. A method for solving key equation polynomials in decoding error correction codes according to claim 13, wherein said method can eliminate the finite-field inverter (FFI) to finish.

19. A method for solving key equation polynomials in decoding error correction codes according to claim 13, wherein said method is only needed t iteration decoding procedure.

20. A method for solving key equation polynomials in decoding error correction codes according to claim 13, wherein said method including said decomposed technique which can also drastically reduce the required number of finite-field multipliers (FFMs) from 4t˜6t to 3.

21. An apparatus for solving key equation polynomials in decoding error correction codes according to claim 1, wherein said method including said decomposed technique that uses only 4t+2ρ+4 registers.

22. A method for solving key equation polynomials in decoding error correction codes according to claim 13, wherein said method including said decomposed technique which no FFIs is presented to implement the inversionless Euclidean algorithm.

23. A method for solving key equation polynomials in decoding error correction codes according to claim 13, wherein said method including said decomposed technique which can also use to calculate the Forney syndrome polynomial.

24. A method for solving key equation polynomials in decoding error correction codes according to claim 13, wherein said method and apparatus is further operable in communication.

25. A method for solving key equation polynomials in decoding error correction codes. In particular, a novel method for inversionless decomposed architecture which is frequently used in BCH and Reed-Solomon decoders, wherein improving process including;
(a) improved the speed of said Educlidean algorithm;
(b) embellished said decoded procedure to reduce half decoded result;
(c) combined the calculate which said errata locator polynomial and errata evaluator polynomial.

26. A mothed as recited in claim 25, wherein said Educlidean algorithm and time is shared said finite-field multipliers (FFMs).

27. A mothed as recited in claim 25, wherein said method can reduce said hardware area.

28. A mothed as recited in claim 25, wherein said modified Educlidean algoridean is a decomposed architecture, eliminated the limit of finite-field inversionless

29. A mothed as recited in claim 25, wherein said inversionless Educlidean algoridean including total iteration number of degree is less than t but also other architectures requires at most 2t interations.

30. A mothed as recited in claim 28, wherein said inversionless Educlidean algoridean use the degree of said error locator polynomial increase from ρ+1 to ρ+t.

31. A mothed as recited in claim 25, wherein said inversionless Educlidean algoridean, the number of total iterations in our modified procedure is less than t.

32. A method for solving key equation polynomials in decoding error correction codes. In particular, a novel method for inversionless decomposed architecture which is frequency used in BCH and Reed-Solomon decoders including:
(a) each iteration could eliminate at least one degree;
(b) combined the hardware of said errata locator polynomial and errata evaluator polynomial;
(c) a number of FFMs is reduced to 3.

33. A mothed as recited in claim 32, wherein said speed of inversionless Educlidean algoridean slowing down, but it will not impact the decoding speed.

34. A mothed as recited in claim 32, wherein said BCH and Reed-Solomon (RS) decoder, Digital Versatile Disks (DVDs) use a RS product code which is (182,172) in the row direction and (208,192) in the column direction.

35. A mothed as recited in claim 32, wherein said BCH and Reed-Solomon (RS) decoder, digital TV broadcasting uses a (204,188) RS code.

36. A mothed as recited in claim 32, wherein said BCH and Reed-Solomon (RS) decoder, CD-ROM uses a number of smaller RS codes, including (32,28),(28,24).

37. A mothed as recited in claim 32, wherein said BCH and Reed-Solomon (RS) decoder, in wireless communications, the AMPS cellular phone system uses (40,28) and (48,36) binary BCH codes, which are shortened codes of the (63,51) code.
